(19) United States
(12) Patent Application Publication
(10) Pub. No.: US 2012/0181067 A1
(43) Pub. Date: Jul. 19, 2012

(54) CIRCUIT BOARD

(75) Inventors: HSIANG-SHENG WEN, Pingzhen City (TW); CHING-FENG HSIEH, Taipei City (TW)

(73) Assignee: ASKEY COMPUTER CORP., TAIPEI (TW)

(21) Appl. No.: 13/040,461

(22) Filed: Mar. 4, 2011

(30) Foreign Application Priority Data
Jan. 14, 2011 (TW) 100101404

(51) Int. Cl. H05K 1/00

(52) U.S. Cl. 174/252

(57) ABSTRACT

A circuit board includes a substrate, a first copper layer, a first solder mask, a second copper layer, and a second solder mask. The substrate has a first surface, an opposing second surface, and a conductive portion bypassing a laid-out circuit and passing through the first and second surfaces. The first and second copper layers are disposed on the first and second surfaces and connected to the conductive portion, respectively. The first and second solder masks are disposed on the first and second copper layers and provided with a first opening corresponding in position to a power component and a second opening for exposing the conductive portion and a portion of the second copper layer, respectively. Heat generated by the power component is transferred by the conductive portion to the second copper layer through the first copper layer and then dissipated to the outside through the second opening, better.

### CROSS-REFERENCE TO RELATED APPLICATION

This non-provisional application claims priority under 35 U.S.C. §119(a) on Patent Application No(s). 100101404 filed in Taiwan, R.O.C. on Jan. 14, 2011, the entire contents of which are hereby incorporated by reference.

### FIELD OF TECHNOLOGY

The present invention relates to circuit boards, and more particularly, to a circuit board for mounting a power component thereon.

### BACKGROUND

Circuit boards, such as printed circuit boards (PCBs) or flexible printed circuits (FPCs), are in wide use with various electronic products. As shown in FIG. 1, a conventional circuit board essentially comprises a substrate 11, a copper layer 12, and a green mask 13, and is configured for use in laying out various electronic components, such as resistors, inductors, capacitors, diodes, transistors, or IC chips, and enabling electrical connection between the electronic components through a circuit layout of the signal-carrying copper layer. A unit or chip-type component that comprises a plurality of electronic components generates high heat when operating is known as a power component 10. The prior art usually requires the use of heat-dissipating components, such as fans or cooling fins, and entails giving considerations to the positions of and distances between the components mounted on a circuit board in order to avoid overheating the components, deteriorating the performance of the components, or even damaging the components. However, given the ongoing technological development and the ever-increasing demand for consumer products, there is a trend toward compact electronic products. As a result, a laid-out circuit of a circuit board and the power components 10 mounted thereon are becoming closer and smaller and thus accumulating more heat than ever before.

The power components 10 presently for use in miniaturized or portable electronic products are mostly surface mounted devices (SMDs), such as chip resistors (also known as SMD resistors), chip capacitors, SMD inductors, or various IC chips, and are in direct contact and/or electrical connection with the internal laid-out circuit or the copper layer 12 of the circuit board, as shown in FIG. 1. Hence, SMDs of considerable height preclude the installation of heat-dissipating components, such as fans or cooling fins, in the crowded space inside an electronic products; as a result, the heat generated by the power component 10 can only be transferred through the copper layer 12 in the circuit board, thus compromising heat dissipation. In addition, the path of electric current includes a ground copper layer of the circuit board, the signal-carrying copper layer that forms the laid-out circuit of the circuit board, and the laid-out circuit, which generate heat; as a result, heat accumulates at specific blocks having laid-out circuit patterns. Furthermore, the copper layer 12 is covered with the green mask 13 thereon, and thus it is difficult for heat to be dissipated to the environment through the copper layer 12.

To enhance heat dissipation, it is feasible to apply a heat dissipation coating (such as a thermal paste or a thermal grease) to the surface of the power component 10 mounted on a conventional circuit board, or mount a heat-dissipating device 14 (such as cooling fins or a fan). Given the aforesaid means of dissipating heat, heat generated by the power component 10 in operation is removed, so as to dissipate heat and decrease temperature and thereby prevent the deterioration of performance of the power component 10 and the electronic product. However, the surface area of the power component 10 is a limiting factor in the efficiency of heat dissipation effectuated by applying the heat dissipation coating to the surface of the power component 10; hence, the heat dissipation coating is of little use for miniaturized SMDs. Also, although cooling fins or fans are effective in dissipating heat, their volume goes against the requirement for miniaturization of electronic products, and they are of limited application to all kinds of compact electronic products.

Accordingly, the conventional circuit board is not effective in dissipating heat, and thus heat continuously generated by a power component in operation is accumulated inside the circuit board rather than efficiently dissipated, to thereby raise the internal temperature of the power product and compromise the performance of the power component and the electronic product.

### SUMMARY

To solve the problem with a conventional circuit board regarding the inefficiency of a power component mounted thereon in dissipating heat, it is an objective of the present invention to provide a circuit board conducive to enhancement of heat dissipation of the power component mounted thereon.

In order to achieve the above and other objectives, the present invention provides a circuit board for mounting a power component thereon. The circuit board comprises: a substrate having a first surface, a second surface opposing the first surface, a laid-out circuit disposed between the first surface and the second surface, and a conductive portion bypassing the laid-out circuit, passing through the first surface and the second surface, and corresponding in position to the power component; a first copper layer disposed on the first surface and connected to the conductive portion; a first solder mask disposed on the first copper layer and provided with a first opening corresponding in position to the power component; a second copper layer disposed on the second surface and connected to the conductive portion so as to receive heat from the power component through the conductive portion; and a second solder mask disposed on the second copper layer and provided with a second opening for exposing the conductive portion and a portion of the second copper layer so as to dissipate heat.

The conductive portion of the circuit board comprises through-holes penetrating the first surface and the second surface, and conductive bodies disposed in the through-holes, respectively. The conductive bodies are made of a conductor or an insulator.

The conductive portion of the circuit board penetrates the first surface and the second surface of the substrate, the first copper layer, and the second copper layer. The conductive portion can be a plated through hole (PTH).

At least a solder joint is disposed on an exposed portion of the second copper layer.

The circuit board further comprises a heat-dissipating body in direct contact with the second copper layer exposed from the second opening. The heat-dissipating body is at least one of a thermal grease, a plurality of cooling fins, a fan, and a casing.

The substrate of the circuit board is one of a bilayer substrate and a multilayer substrate.

Compared with a conventional circuit board, a circuit board of the present invention comprises: a conductive portion for transferring heat generated by a power component to a second copper layer through a first copper layer; a second solder mask having a second opening for dissipating the heat to the environment; and a solder joint, a heat-dissipating body, or a heat-dissipating device disposed on the second copper layer exposed from the second opening to further enhance heat dissipation. Accordingly, the circuit board of the present invention stops the temperature of the power component from rising despite the operation thereof and prevents heat from accumulating in the circuit board.

### BRIEF DESCRIPTION OF THE DRAWINGS

To enable persons skilled in the art to fully understand the objectives, features, and advantages of the present invention, the present invention is hereunder illustrated with specific embodiments in conjunction with the accompanying drawings, in which:

FIG. 1 (PRIOR ART) is a schematic view of a conventional circuit board;

FIG. 2 is a schematic view of a circuit board according to a first embodiment of the present invention;

FIG. 3 is schematic view of a conductive portion not passing through a first copper layer of the circuit board according to the first embodiment of the present invention;

FIG. 4 is a schematic view of the circuit board according to a second embodiment of the present invention;

FIG. 5 is a schematic view of the circuit board according to a third embodiment of the present invention;

FIG. 6 is a schematic view of the circuit board according to a fourth embodiment of the present invention; and

FIG. 7 is a schematic view of a circuit board according to a fifth embodiment of the present invention.

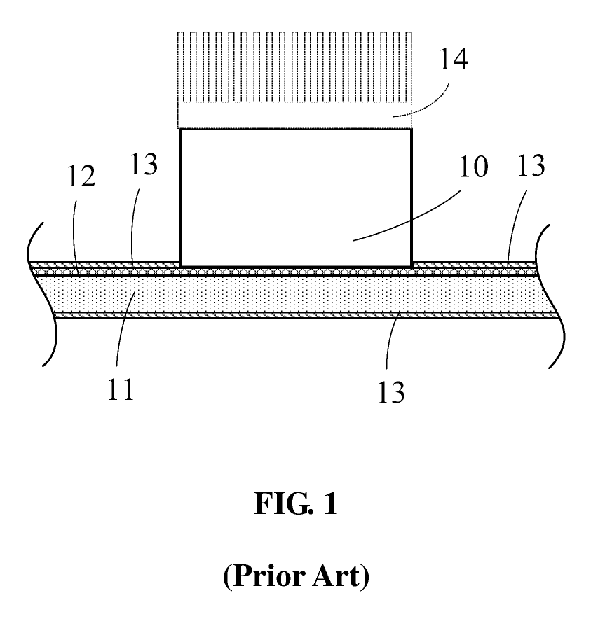

### DETAILED DESCRIPTION

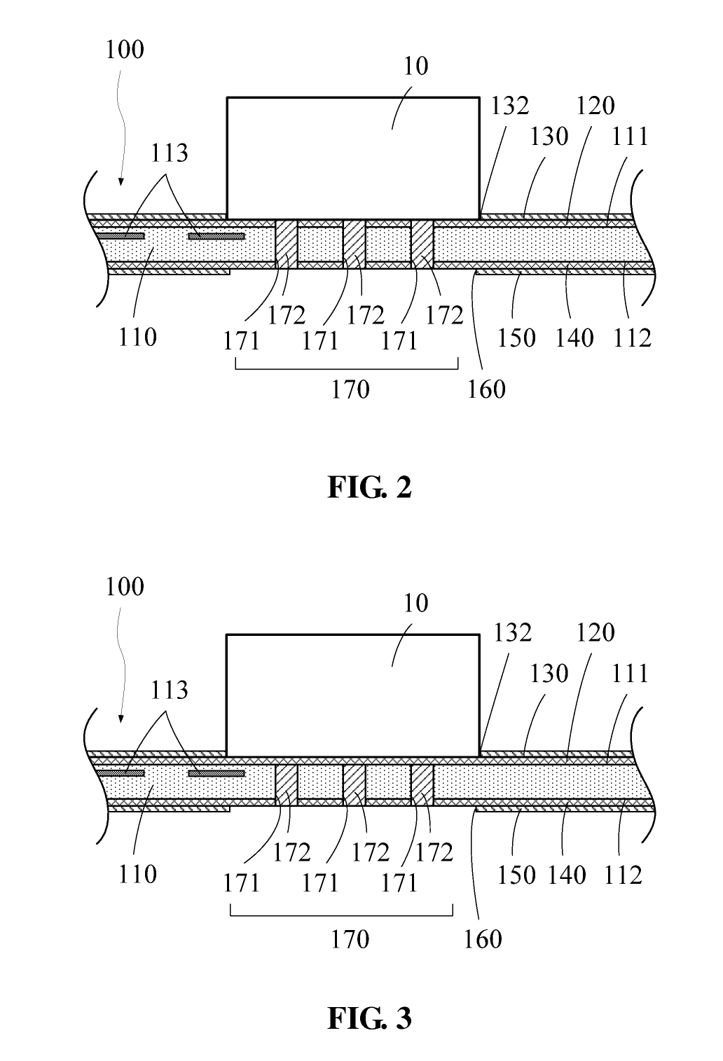

Referring to FIG. 2, there is shown a schematic view of a circuit board 100 according to a first embodiment of the present invention. The circuit board 100 is configured for mounting a power component 10 thereon, and comprises a substrate 110, a first copper layer 120, a first solder mask 130, a second copper layer 140, and a second solder mask 150. The substrate 110 has a first surface 111, a second surface 112 opposing the first surface 111, a laid-out circuit 113 disposed between the first surface 111 and the second surface 112, and a conductive portion 170 bypassing the laid-out circuit 113, passing through the first surface 111 and the second surface 112, and corresponding in position to the power component 10, so as to effectuate the shortest path of heat transfer. The first copper layer 120 is disposed on the first surface 111 and connected to the conductive portion 170. The first solder mask 130 is disposed on the first copper layer 120 and provided with a first opening 132 corresponding in position to the power component 10. Hence, the power component 10 is electrically connected to the laid-out circuit 113 through the first opening 132. The second copper layer 140 is disposed on the second surface 112 and connected to the conductive portion 170 so as to receive heat energy from the power component 10 through the conductive portion 170, thereby effectuating heat dissipation of the power component 10. The second solder mask 150 is disposed on the second copper layer 140 and has a second opening 160 for exposing the conductive portion 170 and a portion of the second copper layer 140. Hence, a portion of the second copper layer 140 is exposed from the second opening 160. The heat of the conductive portion 170 is dissipated to the environment by means of the high thermal conductivity of metal, so as to enhance heat dissipation.

The first opening 132 and the second opening 160 of the circuit board 100 correspond in position to each other and are disposed on the two opposing sides of the circuit board 100, respectively. Heat is transferred from the power component 10 to the environment through the first copper layer 120, the conductive portion 170, and the second copper layer 140, that is, taking the shortest path of heat transfer. The size and quantity of the second openings 160 and the size, quantity and distribution density of the conductive portions 170 depend on the arrangement of the power components 10 and the laid-out circuits 113 of the circuit board 100. For example, the power component 10 of a large surface area can work in conjunction with a plurality of said conductive portions 170 and the second opening 160 of a large size so as to enhance heat dissipation. Alternatively, the second opening 160 can correspond in position to a plurality of said power components 10. This embodiment is exemplified by one said second opening 160 and three said conductive portions 170, but the present invention is not limited thereto.

Referring to FIG. 2, the conductive portion 170 of the circuit board 10 further comprises through-holes 171 penetrating the first surface 111, the second surface 112, the first copper layer 120, the second copper layer 140, and conductive bodies 172 disposed in the through-holes 171, respectively. The conductive bodies 172 are made of a conductor or an insulator. For example, the conductive bodies 172 can be solid metal rods (copper rods or solder rods) or metallic film (copper film or copper foil). The first copper layer 120 and the second copper layer 140 are of equal potential, by functioning either as signal layers or as ground layers concurrently, so as not to result in a short circuit. Alternatively, the conductive bodies 172 are made of a thermal grease of high thermal conductivity or any conductive soft material for filling the through-holes 171 to effectuate the thermal connection between the first copper layer 120 and the second copper layer 140. It is feasible for the conductive portion 170 not to penetrate the first copper layer 120, as shown in FIG. 3. To be specific, the through-holes 171 of the conductive portion 170 penetrate the first surface 111, the second surface 112, and the second copper layer 140 in a manner that one end of each of the conductive bodies 172 in the through-holes 171 is in tight contact with the first copper layer 120, so as to enhance heat dissipation.

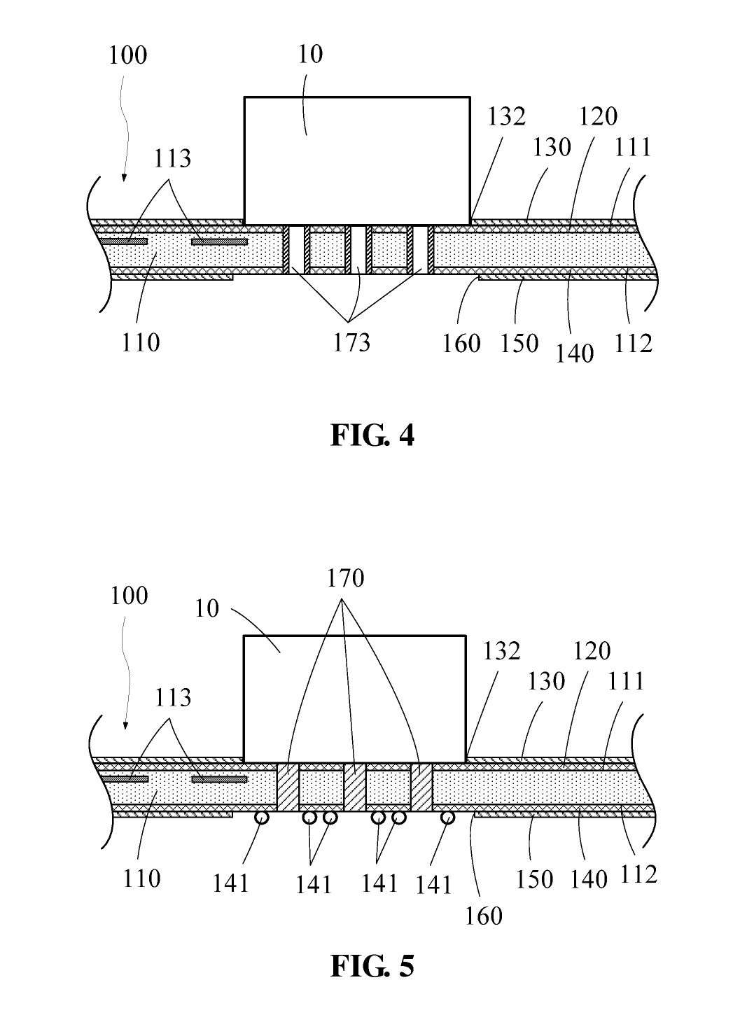

Referring to FIG. 4, there is shown a schematic view of the circuit board 100 according to a second embodiment of the present invention. The conductive portion 170 of the circuit board 100 bypasses a laid-out circuit 113 of the substrate 110 and passes through the first surface 111 and the second surface 112 of the substrate 110, the first copper layer 120, and the second copper layer 140, such that the conductive portion 170 is exposed from the second opening 160. For example, the conductive portion 170 comes in the form of a plated through hole (PTH) 173. The PTH 173 is a through hole with an inner wall electroplated with metal, such as copper or tin, such that a metal-electroplated layer is formed on the inner wall. The conductive portion 170 is in direction contact with the first copper layer 120 and the second copper layer 140. Heat generated by the power component 10 in operation is transferred from the power component 10 to the first copper layer 120, then from the first copper layer 120 to the PTH 173, and finally from the PTH 173 to the second copper layer 140 whereby the heat is dissipated to the environment. The first copper layer 120 and the second copper layer 140 are of equal potential, by functioning either as signal layers or as ground layers concurrently, so as not to result in a short circuit.

Referring to FIG. 5, there is shown a schematic view of the circuit board 100 according to a third embodiment of the present invention. The circuit board 100 further comprises at least a solder joint 141, preferably a plurality of said solder joints 141, disposed on the second copper layer 140 exposed from the second opening 160; in doing so, not only is the surface area of heat dissipation increased, but the second copper layer 140 is prevented from rusting which will otherwise impede heat dissipation. Furthermore, the second copper layer 140 which is exposed from the second opening 160 but is not covered with the solder joints 141 can be covered with an organic solderability preservative layer for preventing the second copper layer 140 from oxidation.

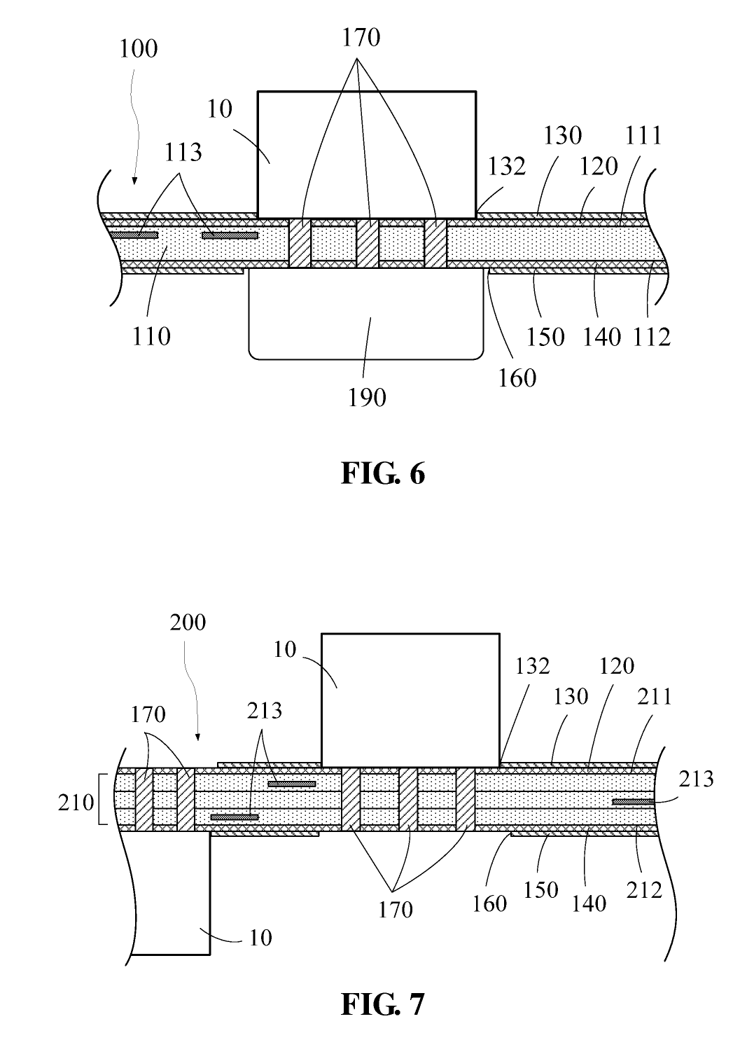

Referring to FIG. 6, there is shown a schematic view of the circuit board 100 according to a fourth embodiment of the present invention. The circuit board 100 further comprises a heat-dissipating body 190. The heat-dissipating body 190 is in direct contact with the second copper layer 140 exposed from the second opening 160. The heat-dissipating body 190 is, for example, a thermal grease, a plurality of cooling fins, a fan, a casing, and/or a selective combination thereof; hence, heat is removed from the second copper layer 140 by the cooling fins or the thermal grease of high thermal conductivity, the casing of a large surface area for heat dissipation, and/or the fan capable of causing forcible convection, so as to further enhance heat dissipation.

Referring to FIG. 7, there is shown a schematic view of a circuit board 200 according to a fifth embodiment of the present invention. The circuit board 200 comprises a substrate 210 which comes in the form of a bilayer substrate or a multilayer substrate. Hence, the fifth embodiment not only features the power component 10 being disposed on a first surface 211 and a second surface 212 of the circuit board 200, but also enables the substrate 210 to accommodate a larger number of laid-out circuits 213 than the preceding embodiments do, so as to increase the utilization rate and layout area of the circuit board 200, facilitate miniaturization of electronic products, and enable high-density distribution of components on the circuit board 200.

The first solder mask 130 and the second solder mask 150 for use with the circuit boards 100, 200 can be a solder resist ink or a green mask for insulating and protecting the circuit boards 100, 200 and thereby preventing oxidation of a copper layer and solder short.

The present invention is disclosed above by preferred embodiments. However, persons skilled in the art should understand that the preferred embodiments are illustrative of the present invention only, but should not be interpreted as restrictive of the scope of the present invention. Hence, all equivalent modifications and replacements made to the aforesaid embodiments should fall within the scope of the present invention. Accordingly, the legal protection for the present invention should be defined by the appended claims.

What is claimed is:

1. A circuit board for mounting a power component thereon, the circuit board comprising:
a substrate having a first surface, a second surface opposing the first surface, a laid-out circuit disposed between the first surface and the second surface, and a conductive portion bypassing the laid-out circuit, passing through the first surface and the second surface, and corresponding in position to the power component;
a first copper layer disposed on the first surface and connected to the conductive portion;
a first solder mask disposed on the first copper layer and provided with a first opening corresponding in position to the power component;
a second copper layer disposed on the second surface and connected to the conductive portion so as to receive heat from the power component through the conductive portion; and
a second solder mask disposed on the second copper layer and provided with a second opening for exposing the conductive portion and a portion of the second copper layer so as to dissipate heat.

2. The circuit board of claim 1, wherein the conductive portion comprises through-holes penetrating the first surface and the second surface, and conductive bodies disposed in the through-holes, respectively.

3. The circuit board of claim 2, wherein the conductive bodies are made of one of a conductor and an insulator.

4. The circuit board of claim 1, wherein the conductive portion penetrates the first surface and the second surface of the substrate, the first copper layer, and the second copper layer.

5. The circuit board of claim 4, wherein the conductive portion is a plated through hole (PTH).

6. The circuit board of claim 1, wherein at least a solder joint is disposed on an exposed portion of the second copper layer.

7. The circuit board of claim 1, further comprising a heat-dissipating body in direct contact with the second copper layer exposed from the second opening.

8. The circuit board of claim 6, wherein the heat-dissipating body is at least one of a thermal grease, a plurality of cooling fins, a fan, and a casing.

9. The circuit board of claim 1, wherein the substrate is one of a bilayer substrate and a multilayer substrate.
